(19) United States
(12) Patent Application Publication
(10) Pub. No.: US 2002/0179366 A1
(43) Pub. Date: Dec. 5, 2002

(54) Speaker assembly having baffle tube

(76) Inventor: Lung-Tan Chen, Taichung (TW)

Correspondence Address: BACON & THOMAS, PLLC, 625 SLATERS LANE, FOURTH FLOOR, ALEXANDRIA, VA, 22314

(21) Appl. No.: 09/873,257

(22) Filed: Jun. 5, 2001

(51) Int. Cl. H05K 5/00

(52) U.S. Cl. 181/156; 181/148

(57) ABSTRACT

An audio box having a front panel with a driving unit fixedly mounted thereon. The driving unit includes a diaphragm driving by electronic circuit. At least a baffle tube is integrally formed with said front panel directing converted rearward audio wave forwardly thereby increasing bass effect.

### FIELD OF THE INVENTION

The present invention relates to a speaker assembly, and more particularly to a speaker assembly with a baffle tube integrally formed on a front panel on which a resonating diaphragm unit is attached.

### DESCRIPTION OF THE PRIOR ART

Conventionally, a speaker enclosure generally includes a box having a front panel on which a driving unit is attached. The driving unit includes a diaphragm driven by an electronic device thereby creating audio wave. However, the audio wave generated by the diaphragm emits forwardly and rearward and each carries a phase opposite to each other. If the forward and rearward audio wave is not separately isolated, the forward and rearward audio waves will interfere with each other thereby creating a noise which has to be eliminated. Accordingly, the panel is especially important to create a clear and sharp audio sound.

In addition, the box shall be also provided with a hole such that the audio wave will not generate an echo or noise within the box. Theoretically, the large the hole, the small the echoing. Nevertheless, the larger the hole, the larger the interference is created by the forward and rearward audio wave.

In order to reduce the interference resulted from the opening of the hole, a confined box is provided with a baffle tube which can correctly convey a rearward audio wave along a direction of the forward audio wave after a phase conversion. By this arrangement, the converted rearward audio wave amplify the base as well as avoid interference between the forward and rearward audio waves. As shown in FIG. 1, a conventional audio box 1 with a speaker unit 11 mounted on a panel 10 fixed to the audio box 1. The panel 10 is provided with an opening 12 in which a baffle tube 13 is fixedly secured thereto by adhesive or other mechanical arrangements. Theoretically, the opening 12 and the baffle tube 13 can be suitably aligned and connected. However, there is always a misalignment or offset between two connected elements, no doubt the connection between the opening 12 and the baffle tube 13. As a result, even the rearward audio wave is converted and directed forwardly through the baffle tube 13, as there is an offset between the opening 12 and the baffle tube 13, there is always an interference between the forward audio wave and forwarded converted rearward audio wave. Consequently, the quality of the audio sound will be impaired. In addition, attaching the baffle tube 13 to the opening 12 is quite laborious.

### SUMMARY OF THE INVENTION

It is an object of this invention to provide a mounting panel of an audio box in which a baffle tube is integrally formed with the panel thereby eliminating interference forward and converted rearward wave.

In order to achieve the object set forth, a front panel to be mounted on an audio box in accordance with the present invention comprises a driving unit fixedly mounted thereon and includes a diaphragm driving by electronic circuit. At least a baffle tube is integrally formed with said front panel directing converted rearward audio wave forwardly thereby increasing bass effect.

### BRIEF DESCRIPTION OF THE DRAWINGS

Other objects and further features of the present invention will be apparent from the following detailed description when read in conjunction with the accompanying drawings, in which:

FIG. 1 is a perspective view of a conventional audio box;

FIG. 2 is similar to FIG. 1 viewed from a reverse direction;

FIG. 3 is a perspective view of a panel in accordance to a first embodiment of the present invention;

FIG. 4 is a cross sectional view of FIG. 3;

FIG. 5 is similar to FIG. 3 with a driving unit mounted thereon;

FIG. 6 is a perspective view of a panel in accordance to a second embodiment of the present invention; and

FIG. 7 is a cross sectional view of FIG. 6.

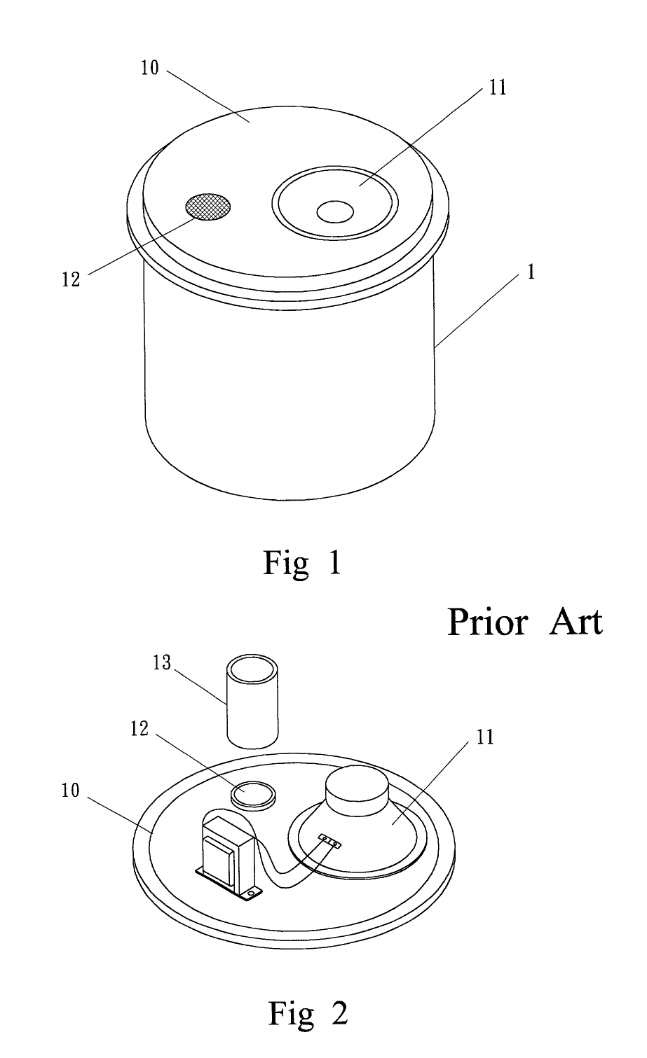

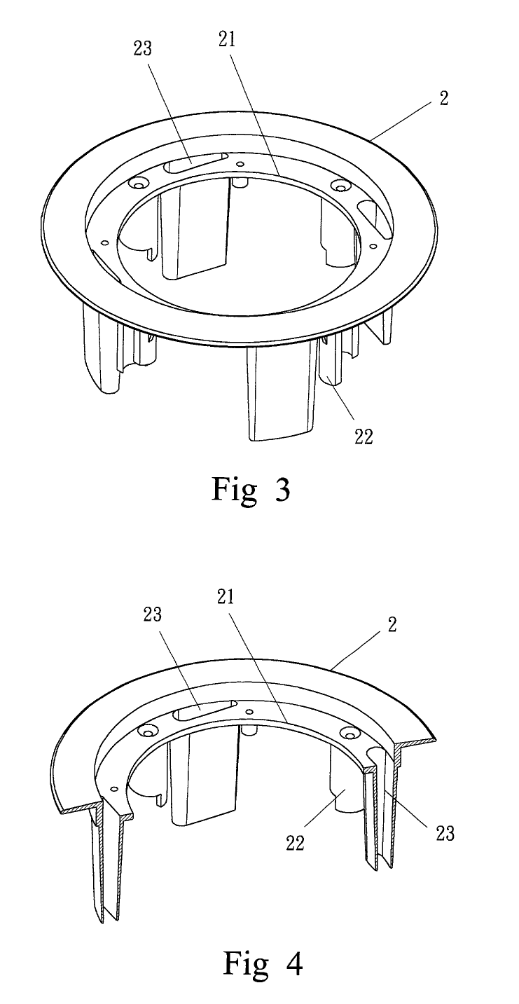

### DETAILED DESCRIPTION OF PREFERRED EMBODIMENT

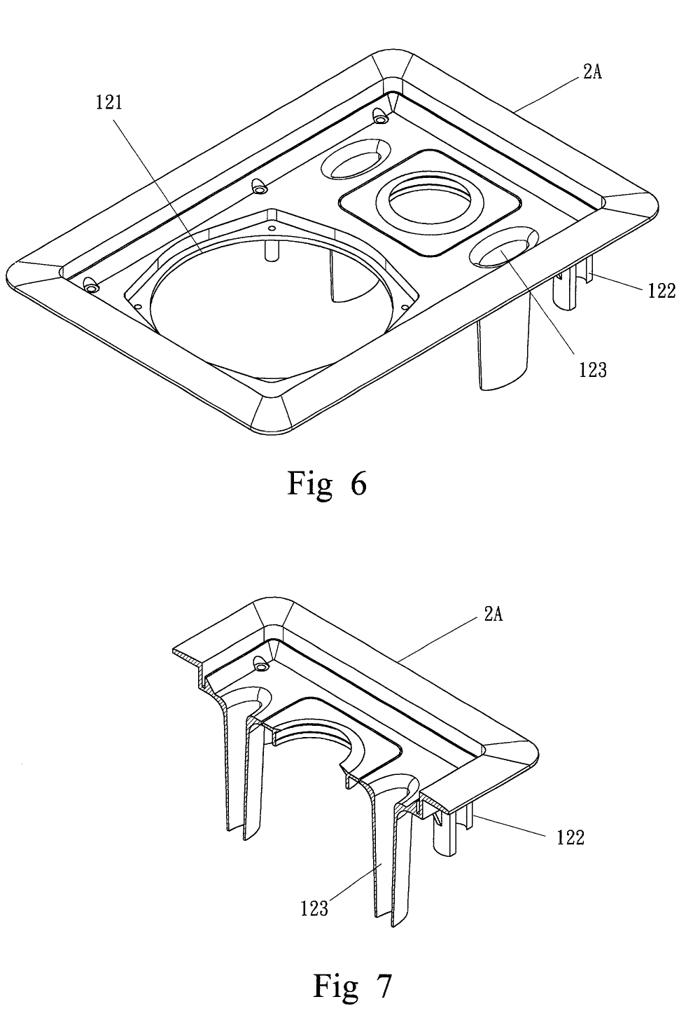

Referring to FIGS. 3 to 7, a front panel 2 to be mounted to an audio box may have a round shape, FIG. 3, and a rectangular shape FIG. 6. The panel 2 defines a first opening 21 in which a driving unit 24 is attached thereto. The panel 2 further includes a plurality of supporting posts 22.

As shown in FIG. 3, four baffle tubes 23 are integrally formed with the panel 2 and surrounding the first opening 21 thereby enhancing the sound quality. The baffle tube 23 defines an aperture defined on the panel 2, and a second end extending rearward, which is clearly shown in FIG. 4. As discussed above, the baffle tube 23 is integrally formed with the panel 2 thereby eliminating any offset or misalignment of thereof and benefiting interference free audio sound. As a result, the converted rearward audio sound can be correctly directed forward thereby enhancing bass effect. In addition, since the interference is properly attenuated, audio quality is also enhanced.

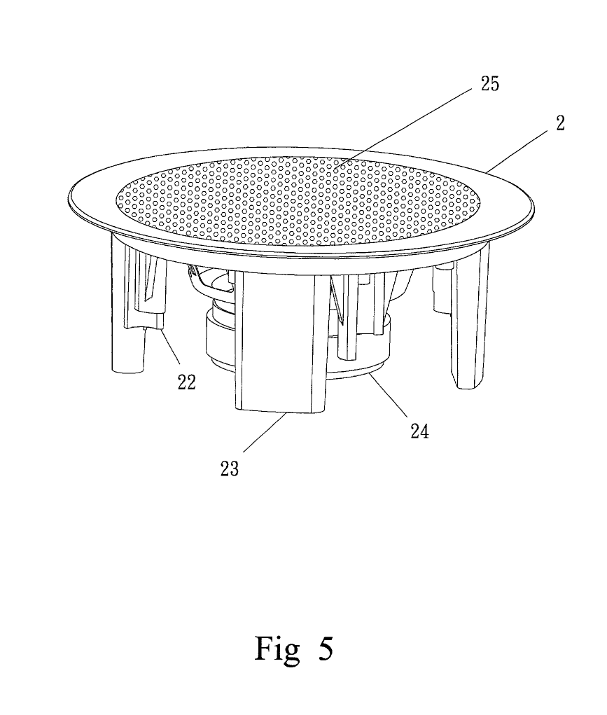

As shown in FIG. 5, the driving unit 24 is attached to the panel 2 with a manner similar to the prior art. However, the panel 2 made in accordance the present invention is integrally formed with four baffle tubes 23 for enhancing the sound quality. The driving unit 24 further includes a protecting cover 25.

FIGS. 6 and 7 disclose a second embodiment of the present invention in which a panel 2A is designed with a rectangular shape for mounting on a rectangular box (not shown). In the preferred embodiment, a pair of baffle tubes 123 is arranged adjacent to a tenor driving unit (not labeled). The panel 2A is also provided with a plurality of supporting posts 122 for mounting to the audio box. The panel 2A further includes an opening 121 for mounting a second driving unit such as shown in FIG. 5.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

I claim:

1. A front panel to be mounted on an audio box, comprising:
a driving unit fixedly mounted thereon, including a diaphragm driving by electronic circuit; and
at least a baffle tube integrally formed with said front panel.

2. The front panel as recited in claim 1, wherein said baffle tube defines a front opening conveying converted rearward audio wave forward.

3. An audio box, comprising
a front panel defining at least a first opening and a second opening;
a driving unit fixedly attached to said first opening; and
a baffle tube integrally formed with said front panel in communication with said second opening.

4. The audio box as recited in claim 3, wherein said baffle tube is arranged adjacent to said driving unit.

5. An audio box, comprising:
a front panel defining at least a first opening;
a driving unit fixedly attached to said first opening; and
a pair of baffle tubes symmetrically arranged adjacent to said driving unit.
